(19) United States
(12) Patent Application Publication
(10) Pub. No.: US 2019/0366298 A1
(43) Pub. Date: Dec. 5, 2019

(54) MAGNETIC FIELD ENHANCED PLASMA FOR MATERIALS PROCESSING

(71) Applicant: BOARD OF TRUSTEES OF MICHIGAN STATE UNIVERSITY, East Lansing, MI (US)

(72) Inventors: Qi Hua FAN, Okemos, MI (US); Thomas SCHUELKE, Pinckney, MI (US)

(73) Assignee: BOARD OF TRUSTEES OF MICHIGAN STATE UNIVERSITY, East Lansing, MI (US)

(21) Appl. No.: 16/479,156

(22) PCT Filed: Jan. 17, 2018
(86) PCT No.: PCT/US2018/014034

§ 371 Date: Jul. 18, 2019

Related U.S. Application Data
(60) Provisional application No. 62/448,009, filed on Jan. 19, 2017.

(51) Int. Cl. B01J 20/20; C01B 32/33; C01B 32/336; B01J 20/30; B01J 19/08; C02F 1/469; B01D 53/32; H01J 37/32

(52) U.S. Cl. CPC B01J 20/20; C01B 32/33; C01B 32/336; B01J 20/3085; B01J 19/087; C02F 1/4691; C02F 2103/08; H01J 37/32669; H01J 37/321; B01J 2219/0896; B01J 2219/0852; B01J 2219/0879; B01D 53/326

(57) ABSTRACT

A method, system and equipment (31) for activating biochar (29) includes flowing a reactive gas into a chamber (33; 305), using an electrical field to create a plasma (75) in the chamber, using a magnetic field (105) to increase density of the plasma and activating biochar with the plasma in the chamber. Use of inductive magnetic coil(s) (131) with an essentially closed loop magnetic field, and/or a permanent magnet(s) (101; 317) are also provided in a further aspect of the present method and apparatus. Another aspect causes magnetic densification of one or multiple plasmas in a chamber (305) to treat a previously produced layer of thin film (303).

### CROSS-REFERENCE TO RELATED APPLICATIONS

This application claims the benefit of U.S. Provisional Application No. 62/448,009, filed on Jan. 19, 2017. The entire disclosure of the above application is incorporated by reference herein.

### GOVERNMENT RIGHTS

This invention was made with government support under 1536209 awarded by the National Science Foundation. The government has certain rights in the invention.

### BACKGROUND AND SUMMARY

The present disclosure relates generally to plasma equipment and methods, and more specifically to a magnetic field enhanced plasma.

U.S. Patent Publication No. 2016/0322174, entitled “Method for Plasma Activation of Biochar Material” and co-invented by the present inventor Q. Fan, discloses a method to activate biochar by use of radio frequency (“RF”) power to create a plasma. This patent publication is incorporated by reference herein. While this '174 Fan patent publication is a significant advance in the industry, further processing efficiencies are now desirable.

Plasma arc torches using a magnetic field are also known although entirely unrelated to activating biochar; for example, U.S. Patent Publication No. 2015/0041454, entitled “Plasma Whirl Reactor Apparatus and Methods of Use” which published to Foret on Feb. 12, 2015, and is incorporated by reference herein. This '454 Foret patent publication relates to use of a plasma torch to treat water flowback produced from hydraulic fracturing in oil fields. It is noteworthy that this conventional plasma arc torch operates at an extremely high temperature. While this conventional whirl reactor could theoretically be used for pyrolysis or making biochar from a biomass, it is unlikely suitable for activating biochar in large-scale mass production.

In accordance with the present invention, a method, system and equipment for activating biochar includes flowing a reactive gas into a chamber, using an electrical field to create a plasma in the chamber, using a magnetic field to increase density of the plasma and activating biochar with the plasma in the chamber. Use of inductive magnetic coil(s) with an essentially closed loop magnetic field, and/or a permanent magnet(s) are also provided in a further aspect of the present method and apparatus. Another aspect causes magnetic densification of one or multiple plasma(s) in a chamber to treat a previously produced layer of a thin film.

The present method and system are advantageous over prior devices. For example and not by way of limitation, the present method and system are capable of much faster biochar activation and therefore, require less expensive vacuum systems and manufacturing costs. It is expected that at least twice and more preferably, at least six times more dense and intense plasma will be created with the present method, system and equipment as compared to that in the '174 Fan patent publication, which leads to significantly greater ion energy, which allows for doping biochar to promote electrical conductivity or activation in a smaller longitudinal space, the use of larger but lower cost vacuum systems, and/or more efficient production throughput for biochar activation and film treatment.

The present method and system advantageously achieve greater plasma density at a lower pressure. Plasma pressure is preferably less than or equal to 100 milliTorr for a permanent magnet construction which is less than in prior devices not employing a magnetic field. The present lower pressure is advantageous since reactive ions in the plasma will have less collision interaction with other particles before activating biochar, thereby reducing energy loss and preserving their kinetic energy, and enabling better control of the properties and microstructures of the processed materials. Additional advantages and features will be disclosed in the following description and claims as well as in the appended drawings.

### BRIEF DESCRIPTION OF THE DRAWINGS

FIG. 1 is a series of diagrams showing biomass, biochar and active biochar;

FIG. 2 is a diagrammatic side view showing one embodiment of magnetic field enhanced plasma equipment;

FIG. 3 is an enlarged diagrammatic side view showing the equipment of FIG. 2;

FIG. 4 is a cross-sectional view, taken along line 4-4 of FIG. 3, showing the equipment of FIG. 2;

FIGS. 5 and 6 are optical spectra comparing expected plasma emission intensity without and with magnetic field enhancement;

FIG. 7 is a diagrammatic side view showing another embodiment of magnetic field enhanced plasma equipment;

FIG. 8 is a perspective view showing the equipment of FIG. 7;

FIG. 9 is a series of side and perspective views showing the present magnetic field enhanced plasma-activated biochar employed in a supercapacitor;

FIG. 10 is a diagrammatic side view showing the present magnetic field enhanced plasma-activated biochar employed in a water desalination system;

FIG. 11 is a diagrammatic side view showing the present magnetic field enhanced plasma-activated biochar employed in a water purification system; and

FIG. 12 is a diagrammatic side view showing another embodiment of the present magnetic field enhanced plasma equipment employed with film treatment.

### DETAILED DESCRIPTION

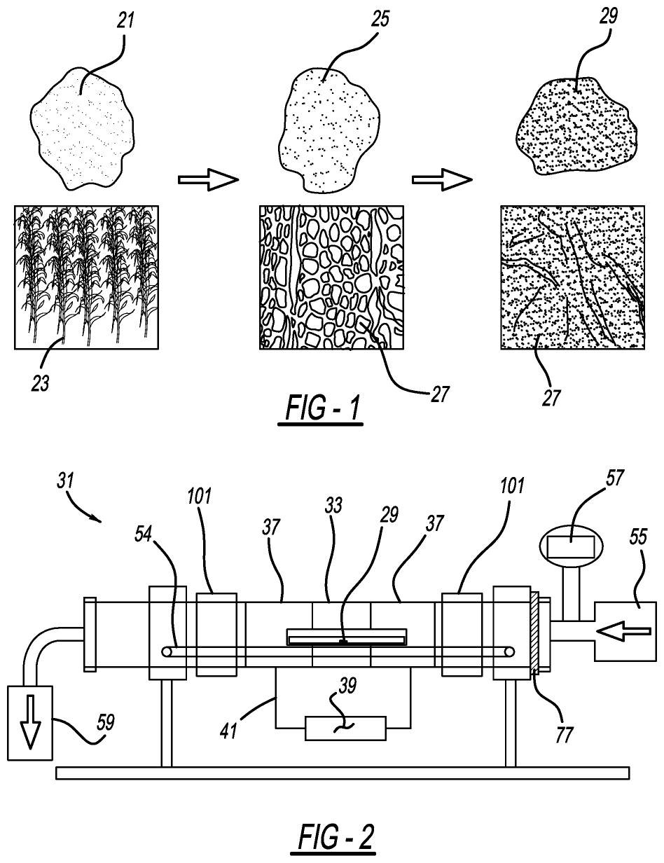

Referring to FIG. 1, biomass 21, as can be obtained from decomposed cornstalks 23, wood or other naturally occurring biodegradable materials, is manufactured into biochar 25 through a manufacturing process known as pyrolysis. Pyrolysis is a thermochemical decomposition of the biomass at elevated temperatures in the absence of oxygen. The biochar usually has pores 27 with sizes of 2-8 μm and wall thicknesses of approximated 1 μm. The biochar must therefore be activated to create activated biochar 29, a microstructure of which is illustrated in the right bottom square of FIG. 1. Activation creates nanostructures with a high surface energy necessary for efficient ionic attraction and/or impurity trapping. Plasma is employed for the activation process and advantageously creates nano-porous morphology while also improving a distribution of different pore sizes which achieves a high specific capacitance. For example, plasma activated biochar includes significantly more mesopores compared with prior chemically activated biochar, which advantageously increases adsorption and/or ion transportation thereby leading to lower impedance and higher specific capacitance.

A first embodiment of a magnetic field enhanced plasma equipment system 31 is illustrated in FIGS. 2-4. This includes a longitudinally elongated vacuum chamber 33, which has a dielectric quartz enclosure or tube, an interior surface 35 of which defines a vacuum cavity or workspace. Alternately, a steel chamber can have a localized quartz window. Conductive copper electrodes 37 are coupled or mounted adjacent to an exterior of vacuum chamber 33 at spaced apart locations. A radio frequency (“RF”) power source 39 is electrically connected to electrodes 37 by way of electrical circuits 41. A grounding electrical circuit 43 is connected to one of electrodes 37. A matching network 45 is electrically connected to at least one of electrodes 37 and includes variable capacitors and/or inductor electronics that can be tuned to match plasma impedance with that of RF power source 39. A cathode 51 of electrodes 37 is electrically connected to RF power supply 39 while an anode 53 of electrodes 37 is connected to ground 43 such that it is negatively biased through variable capacitance or at a floating potential. The anode and cathode are on opposite sides of vacuum chamber 33 and are circumferentially spaced apart from each other. Activated biochar 29 can be disposed directly on the anode by way of a specimen support or on a moving conveyor belt 54 electrically coupled with the anode.

A gas supply cylinder or tank 55 is coupled to an end of vacuum chamber 33, a vacuum meter 57 is coupled adjacent thereto, and a vacuum pump 59 is coupled to an opposite end of vacuum chamber 33. A reactive gas or mixture of such reactive gases flows from gas tank 55 into vacuum chamber 33 at a vacuum pressure lower than nominal ambient atmospheric pressure at sea level. Examples of such reactive gasses include oxygen, hydrogen, nitrogen, argon or other inert gases, or mixtures thereof, optionally including carbon, silane or metalorganic gases. Oxygen is preferably employed. It is noteworthy that low gas pressures are employed, preferably one milliTorr to one Torr, by way of nonlimiting example. Preferably a primary or majority direction of an RF field 71 generated between cathode 51 and anode 53 of electrodes 37, is oriented in a lateral or transverse direction (also denoted as 71) which is generally perpendicular to a longitudinal direction 73 (which is also a movement direction of conveyor 54). Plasma 75 is generated between the electrodes by the RF electrical field acting upon the reactive gas using an excitation power of at least 50 watts, with a radio frequency of preferably 13.56 MHz.

A pre-heater 77 is optionally employed to heat biochar 29 above room temperature but less than 500° C. Pre-heater 77 may be adjacent vacuum chamber 33 or remote therefrom. The creation of plasma 75 creates highly reactive ions 79 that directly contact against the workpiece specimen for etching, surface treatment and/or activation thereof, especially for biochar specimen 29. Furthermore, increasing ion energy can lead to doping to enhance electrical conductivity of the biochar.

A set of static and permanent magnets 101 are coupled or mounted adjacent to an external surface of vacuum chamber 33 in a longitudinally spaced apart manner. Alternately, magnets 101 may be mounted outside of the internal vacuum cavity but inside an optional protective exterior housing defining the chamber equipment. Each permanent magnet 101 is preferably of a large ring or annular shape with a central opening 103 therethrough. An exemplary permanent magnet material is NdFeB, grade MGO 42, with a central axial direction essentially aligned with longitudinal direction 73. Magnetic field 105 flows from one magnet to the other, a majority of which is generally aligned with longitudinal direction 73, albeit in a slightly curved or arcuate path therebetween. In this embodiment, magnetic field 105 primarily flows in a direction perpendicular to a primary majority direction of RF electrical field 71, and certainly in an offset angular direction therefrom. This magnetic field beneficially confines high energy electrons 79 from escaping to electrodes 37. With this magnetic field enhanced plasma process and equipment, the plasma density is advantageously increased at least six times greater than without use of magnetic fields. Furthermore, the magnetic field strength with permanent magnets 101 is preferably 50-4,000 Gauss, and more preferably 100-2,000 Gauss, and even more preferably 200-2,000 Gauss. The present magnetically densified plasma beneficially speeds up the biochar activation process and therefore allows for use of a smaller sized and less expensive production vacuum chamber as compared to without use of the permanent magnets.

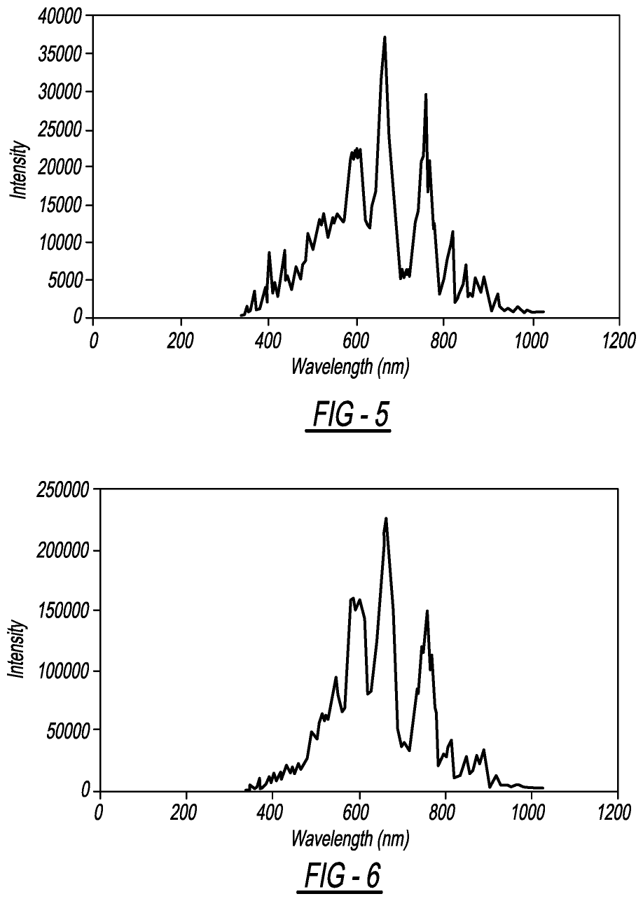

FIGS. 5 and 6 show expected optical emission spectra of plasmas employed for biochar activation. FIG. 5 illustrates the intensity versus wavelength of the plasma created with an RF field but without a magnetic field, while FIG. 6 illustrates the RF created plasma intensity with the present magnetic field. It is noteworthy that the expected plasma intensity increases by more than six times with use of the present magnetic field enhancement.

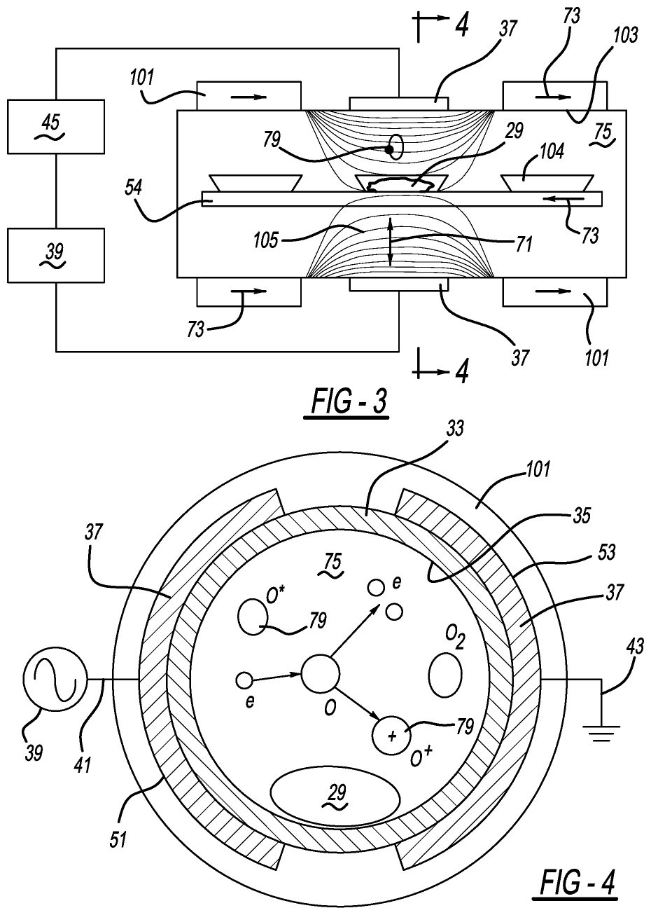

FIG. 2 illustrates a thin (preferably 2-5 mm) layer of biochar 29 longitudinally moving upon longitudinally elongated conveyor belt 54 through the inner openings of magnets 101, between electrodes 37, through RF electric field 71, and through magnetic field 105, during its activation. FIG. 3 illustrates a variation wherein batches of biochar 29 are moved through the vacuum chamber in separate buckets 104 supported by conveyor 54 or the like.

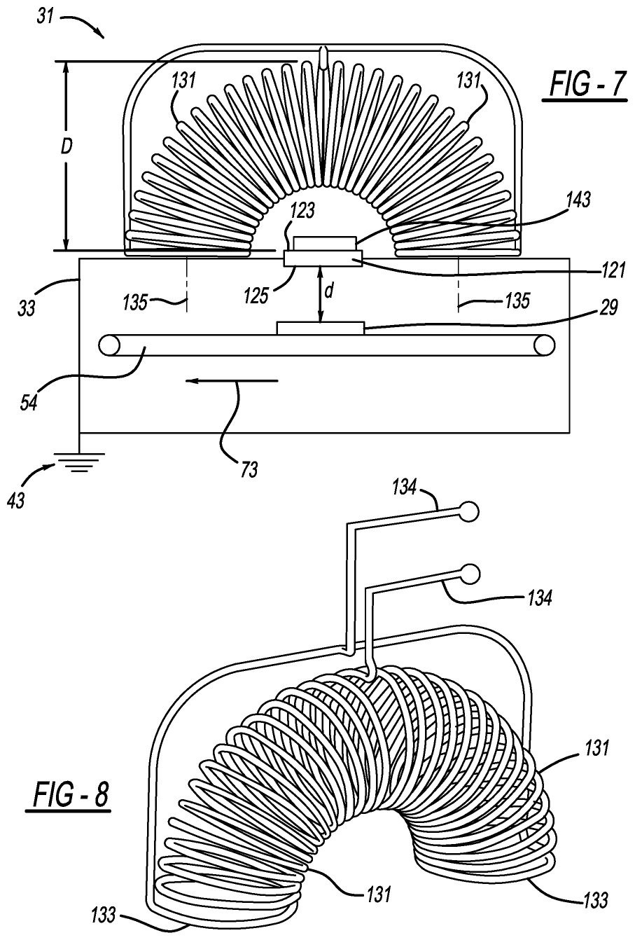

Reference should now be made to FIGS. 7 and 8 showing another equipment embodiment of system 31. A vacuum chamber 33 and conveyor 54 therein are similar to that of the prior embodiment. A localized quartz dielectric window 121, however, is mounted through a hole in a top of metallic steel vacuum chamber 33 and includes generally flat or planar exterior and interior surfaces 123 and 125, respectively. The permanent magnets of the prior embodiment are instead replaced by multiple pairs or sets of helical coils or wires 131. The coils or wires 131 are referred to herein as inductive coil magnets. Each coil 131 includes a distal end 133 which has circular or rectangular shapes in contact against exterior surface 123 of window 121. A central and elongated axis 135 extending the entire length of each coil 131 preferably has a majority which is angularly offset from longitudinal direction 73 and also offset from the perpendicular direction (see 71 in FIG. 3). Each coil includes helical spiral or three-dimensionally wound loops (of circular or generally polygonal end view) with a soft iron core. A lateral distance D between exterior surface 123 of window 121 and a furthest outboard point of each set of coils 131 is preferably greater than a distance d between interior surface 125 of window 121 and a nominally facing surface of biochar specimen 29. An RF electrode 143 is located outboard of and adjacent to exterior surface 123 of window 121 and between distal ends 133 of coils 131.

The present specific induction coil configuration provides a closed loop magnetic field directional path between ends 133 of each set of coils 131. Distal ends 133 of coils 131 are connected to an AC or DC power supply via lines 134. Coils 131 are also preferably grounded such that there is essentially no potential difference at the ends of coils 131 which assists in avoiding plasma etching of window 121. This closed loop magnetic field functionality advantageously reduces magnetic field leakage and subsequent eddy currents in the metallic chamber wall. The present induction magnetic field plasma system and method create much higher density plasma at lower vacuum pressures but also allow for vacuum chamber scalability to larger internal working areas (e.g., one meter wide) which are otherwise difficult to achieve in a cost effective manner. For example, this induction magnetically enhanced plasma embodiment is expected to achieve a plasma density in the vacuum chamber of at least 10¹² cm⁻³, which is more than two orders of magnitude greater than the system of FIG. 2b in U.S. Patent Publication No. 2016/0322174. The induction magnetic coils generate a magnetic field strength of approximately 20-4000 Gauss.

The permanent magnet and induction coil magnet embodiments of the present magnetic field enhanced plasma discussed herein modify the specimen (e.g., biochar) by the plasma that is excited by combined electric and magnetic fields, which are primarily perpendicular to each other in the reaction area inside the vacuum chamber. The plasma of both of these embodiments is generated using at least one reactive or process gas under pressures below one Torr that leads to a mean or average free path of the plasma species equivalent or comparable to a distance between the specimen and the closest interior point of the vacuum chamber.

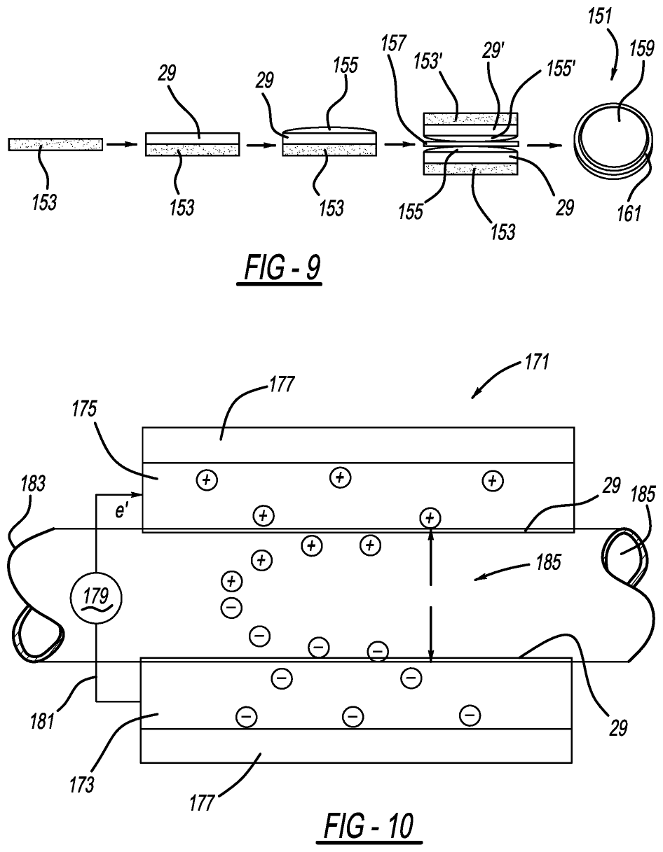

Various exemplary uses of activated biochar 29 will now be discussed with regard to either embodiment of the magnetic field enhanced plasma equipment previously discussed herein. FIG. 9 illustrates use of activated biochar 29 for energy storage, such as in a supercapacitor 151. First, a nickel foil substrate 153 is cut to size. Second, a layer of activated biochar 29 is adhesively or otherwise bonded upon substrate 153. Third, an electrolyte 155 is applied onto an exposed surface of activated biochar 29 on an opposite side from substrate 153. An insulating and separating film layer 157 is then inserted and mounted upon exposed surface of electrolyte 155 opposite biochar layer 29. Fourth, a symmetrically mirrored image sandwich of nickel foil substrate 153′, activated biochar 29′ and electrolyte 155′ is placed upon separator film 157. Finally, exterior conductive metallic housings (electrodes) 159 and 161 are joined together and encase the foil substrates, biochar and electrolyte sandwiches therein to define the end product. Such supercapacitors 151 are suitable for quickly charging and discharging for millions of cycles without degradation. The present supercapacitors act as batteries and are usable in electric automotive vehicles, portable computers and other mobile electronic components. The biochar-based supercapacitor capacity is expected to be greater than 260 F/g.

Referring now to FIG. 10, another use of the present activated biochar is in a water desalination system 171 or an air-purification system in a factory smokestack or the like. Water desalination system 171 employs a layer of activated biochar 29 adhesively bonded or otherwise coupled to an interior surface of positive and negative electrodes 173 and 175, respectively. Current collectors 177 are coupled to exterior portions of the electrodes. Furthermore, a power source such as a voltage cell 179 and other associated electronics are electrically connected to electrodes 173 and 175 by electrical circuitry 181.

Brackish or salt water flows in through inlet 183, travels through a central internal opening 185 of the biochar coated electrodes, and out of a potable and desalinated water outlet 185. Water desalination can be driven by a low voltage, preferably less than 2 volts, generated from power source or cell 179, such as solar panels. The stored charge can be released as electrical energy from collectors 177. Furthermore, it is expected that the magnetic field enhanced plasma-treated biochar should provide at least two times greater electro-sorption capacity as compared to conventional devices that do not employ plasma treatment of biochar.

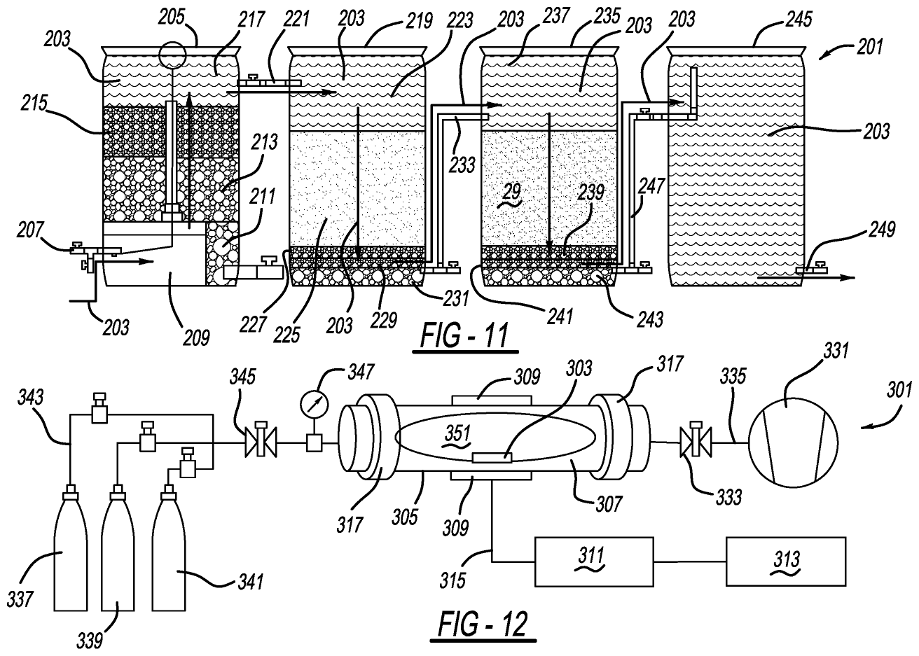

Reference should now be made to FIG. 11. The magnetic field enhanced plasma can be used to activate biochar 29 employed in a water purification system 201. Water 203 enters a first purification tank 205 via a pipe inlet 207. Inflow pressure causes the water to move into inlet 207, into an initial entrance cavity 209, upwardly through a large stone size filtering area 211, through an intermediate stone size filtering area 213, through a fine stone size filtering area 215 and into an upper holding cavity 217. Water 203 is then moved from upper holding cavity 217 to a second tank 219 via a pipe 221. Water 203 is next moved from an upper holding cavity 223 of second tank 219 downwardly through a sand filtering area 225 and through stone filtering areas 227, 229 and 231 of differing sizes or types. Water 203 is subsequently transported via pipe 233 to a third tank 235. Thereafter, water 203 is downwardly moved from an upper holding cavity 237 of third tank 235 through magnetic field enhanced plasma-activated biochar 29 and then through multiple stone filtering areas 239, 241 and 243 of differing stone sizes or types. Moreover, water 203 is flowed from third tank 235 to a final holding tank 245 via pipe 247. An outlet pipe 249 operably supplies the final purified water 203 to end users. It is envisioned that a single pass of the water through this filtering system, including the magnetically field enhanced plasma-activated biochar 29, should be able to trap more than 99% of toxic elements initially therein.

FIG. 12 illustrates a system 301, equipment and a process using the magnetic field enhanced plasma to treat or modify a thin film 303. A vacuum chamber 305, including a longitudinally elongated quartz tube (or metallic housing with one or more dielectric windows) which is sealed on both ends, has an internal vacuum cavity 307 therein. A conveyor is located within the vacuum cavity 307 and longitudinally moves film 303. Furthermore, at least a pair of electrodes 309 are mounted to an exterior of vacuum chamber 305 and a matching electronic network 311 and an associated RF power source 313 are electrically connected to electrodes 309 by way of electrical circuit 315. At least a pair of ring or annular shaped permanent magnets 317 are mounted to an exterior of vacuum chamber 305 surrounding portions of the vacuum cavity therein. Electrodes 309 are centrally located between but spaced away from permanent magnets 317. A vacuum pump 331 is coupled to vacuum chamber 305 via valves 333 and pipes or tubes 335. Moreover, at least three gas sources, cylinders or holding tanks 337, 339 and 341 are connected to vacuum chamber 305 via pipes or tubes 343, and valves 345 with meters 347. Preferably tank 337 contains oxygen, tank 339 contains hydrogen and tank 341 contains nitrogen.

An example of thin film 303 is zinc oxide which is a suitable material for various optoelectronic components since it is a direct and wide band gap semi-conductor. These optoelectronic applications, however, require tuning and controlling of the electrical and optical properties of zinc oxide films 303. The exemplary zinc oxide thin film is prepared by a solution method that leads to oriented crystal growth along its elongated longitudinal plane. The zinc oxide film is sequentially treated with oxygen, hydrogen and then nitrogen plasmas 351 by electrodes 309 creating the plasmas within vacuum chamber 305 by the RF electrical interaction with the reactive gases from tanks 337, 339 and 341, which are advantageously simultaneously densified by the magnetic field from magnets 317. The oxygen plasma treatment improves the crystallinity of the film without affecting the film's transmittance. The hydrogen plasma treatment is effective in improving the electrical conductivity but sacrificing the film's transmittance. Furthermore, the nitrogen plasma treatment improves electrical conductivity without compromising the optical transmittance of the film. It is envisioned that sequential oxygen, hydrogen and nitrogen plasma treatments will significantly reduce the resistivity of zinc oxide thin films by over two orders of magnitude and maintain the transmittance close to the as-deposited initially manufactured films in the invisible wavelength range.

Zinc oxide thin film is initially grown or manufactured by chemical vapor deposition, RF magnetron sputtering, epitaxy, pulse laser deposition, sol-gel method, or metal organic chemical vapor deposition. The film is initially manufactured on a glass substrate. Without subsequent treatment, however, it suffers from relatively poor electrical conductivity due to the high density of carrier traps and potential barriers at the grain boundaries. It is noteworthy that the use of oxygen in the magnetic field enhanced plasma process not only improves the crystallinity but also repairs dangling bonds at grain boundaries in the film. The film thickness is preferably greater than 5 nm and less than 1,000 nm upon the glass substrate.

The RF power source frequency is preferably maintained at 13.56 MHz. More specifically, tank 337 contains oxygen, tank 339 contains hydrogen and tank 341 contains nitrogen, and the gases are introduced into vacuum chamber 305 at no more than two Torr. The oxygen and nitrogen plasmas interact with or modify the film within the vacuum chamber for approximately 20 minutes or less, each, and the hydrogen plasma interacts or modifies the film for a range between 30 seconds and 2 minutes, inclusive. Thus, the total plasma treating time is no more than 60 minutes. The pressures and densities of the three types of plasmas are preferably the same. Optionally, the film is heated prior to introduction of the plasmas. Use of the three different reactive gases and associated plasmas are advantageous as contrasted to use of only one or two of the noted gases and advantageous over a different ordering of such. Again, the present magnetic field enhanced plasma is employed in a post-manufacturing film process or subsequent tuning/modification of the already formed film which is longitudinally moved through the vacuum chamber.

Various embodiments of the present magnetic field enhanced plasma process, system and method have been described although other variations may be made. For example, the induction magnetic construction can be employed with the film treatment process. Furthermore, it is alternately envisioned that multiple reactive gas and plasmas, such as three used with the film treatment process, can be employed with any of the biochar embodiments although such may not be as advantageous. Moreover, other films or specimens can be activated or treated within the magnetic field enhanced plasma processes and equipment disclosed herein, although certain of the present advantages may not be fully realized. Moreover, specimen etching and doping may be performed with the present magnetic field enhanced plasma process or equipment. Specific permanent and inductive magnetic members have been described and shown but other shapes and types may be provided although certain benefits may not be achieved. Another alternate construction places the biochar or other specimen at a bottom of the vacuum chamber, the gas is vertically entering the chamber, and the plasma flows in a downward direction before it is magnetically enhanced while modifying the specimen. Moreover, an air purification electrode is essentially of the same construction as that shown for the water desalination electrodes. Any and/or all of the structural components or functions of any of the previously described embodiments may be mixed and matched and interchanged with any of the other embodiments. Any and/or all of the claims may be multiply dependent upon each other in any combination. It is intended by the following claims to cover these and any other departures from the disclosed embodiments which fall within the true spirit of this invention.

1. A method of increasing plasma density for activating biochar, the method comprising:
(a) placing biochar in a vacuum;
(b) creating an electrical field within the vacuum;
(c) creating plasma with reactive gas in the vacuum;
(d) creating a magnetic field in the vacuum between spaced apart magnets, to increase density of the plasma;
(e) causing a majority flow direction of the magnetic field to be angularly offset from a majority flow direction of the electrical field within the vacuum;
(f) moving the biochar in a longitudinal direction through a vacuum chamber during the creation of the plasma;
(g) causing the majority flow direction of the magnetic field to extend in a substantially parallel direction to the longitudinal direction of movement of the biochar; and
(h) activating the biochar with the increased density plasma.

2. The method of claim 1, wherein the magnets are permanent magnets between which is located at least one RF electrode, the RF electrode assisting in the creation of the plasma.

3. The method of claim 2, wherein each of the permanent magnets are:
(a) annular and longer in the longitudinal direction as compared to a cross-sectional thickness on one side thereof;
(b) located longitudinally external to a majority of the plasma;
(c) located longitudinally external to the biochar when the biochar is centrally located within the vacuum chamber containing the vacuum; and
(d) adjacent but external to the vacuum chamber.

4. The method of claim 1, wherein the vacuum chamber is elongated and straight in the longitudinal direction.

5. The method of claim 1, further comprising energizing a pair of RF electrodes, and the creating of the electrical field being elongated between the electrodes within the vacuum chamber to assist in the creation of the plasma which includes ionized oxygen gas, and the majority flow direction of the electrical field being perpendicular to the longitudinal direction of movement of the biochar.

6. The method of claim 1, wherein the magnetic field has a strength greater than 200 Gauss, the electrical field power is at least 50 watts, and the total activating step takes no longer than 60 minutes.

7. The method of claim 1, wherein the magnets include inductive magnetic coils, the coils being energized by a DC or AC power supply to create a closed loop magnetic field between spaced apart ends of the coils which are closest to a dielectric surface behind which is the vacuum.

8. The method of claim 1, wherein the magnets include both at least one permanent magnet or at least one inductive magnetic coil.

9. The method of claim 1, wherein an RF electrode is located between distal looped ends of inductive magnetic coils, and the RF electrode is also located external to the vacuum.

10. The method of claim 1, further comprising creating a pressure of the vacuum within the vacuum chamber of ten milliTorr to one Torr, and the biochar being activated by the plasma in the vacuum chamber with the plasma density being at least 10¹² cm⁻³.

11. The method of claim 1, further comprising attaching the activated biochar to a water desalination electrode.

12. The method of claim 1, further comprising placing the activated biochar in an air or water purification system.

13. The method of claim 1, wherein the magnets include multiple pairs of helical coils located external to the vacuum chamber containing the vacuum, a circular end of each of the coils face the vacuum chamber, and at least a portion of a central axis extending through each of the coils being angularly offset from an exterior plane of the adjacent portion of the vacuum chamber.

14. A method of increasing plasma density, the method comprising:
(a) flowing a reactive gas into a chamber;
(b) using electrodes to create an RF electrical field in the reactive gas to create a plasma in the chamber;
(c) using spaced apart permanent magnets located adjacent to the chamber to create magnetism, the electrodes being longitudinally located between the permanent magnets;
(d) causing the plasma to have a density of at least 10¹² cm⁻³ by intacting the magnetism with the plasma; and
(e) contacting a specimen with the dense plasma in the chamber to modify the specimen faster than if no magnetism is present.

15. The method of claim 14, wherein each of the permanent magnets is annular with a co-axially aligned central opening, and the specimen is activated between the permanent magnets.

16. The method of claim 14, further comprising:
(a) moving the specimen, which is biochar, in a longitudinal direction through the chamber which is a vacuum chamber; and
(b) the modifying includes activating the specimen, which includes biochar, during the contacting step.

17. The method of claim 14, further comprising:
(a) flowing second and third gases into the chamber, one of the gases being oxygen, one of the gases being hydrogen and one of the gases being nitrogen; and
(b) moving the specimen through the chamber on a glass substrate, the specimen including a thin film being modified after its manufacture onto the substrate.

18. The method of claim 13, further comprising causing pressure of the plasma within the chamber to be 10-100 milliTorr and the chamber including internal dimensions of at least one meter.

19. The method of claim 13, wherein:
the specimen includes a sol-gel processed zinc-oxide film;
the modification occurs after the film has been manufactured onto a substrate; and
the modification improves electrical conductivity of the film without degrading crystallinity and optical transmittance of the film.

20-26. (canceled)

27. A biochar-activation system comprising:
(a) a vacuum chamber;
(b) a specimen-conveyor located within the vacuum chamber which is longitudinally elongated;
(c) a gas source operably supplying reactive gas into the vacuum chamber;
(d) a conductor operably creating an RF electric field to cause the gas to become a plasma;
(e) a magnetic field located within the vacuum chamber to densify the plasma to a density of at least 10¹² cm⁻³ for contact with the specimen; and
(f) the conductor being longitudinally located between areas of the vacuum chamber where the magnetic field longitudinally begins and ends.

28. The system of claim 27, further comprising:
(a) permanent magnets, located outside of the vacuum chamber, creating the magnetic field with the conductor being located between the magnets;
(b) the conductor including electrodes located adjacent a middle section of the vacuum chamber;
(c) the specimen conveyor operably moving the specimen through an opening in each of the magnets, which are annular; and
(d) pressure of the plasma within the chamber being 100 milliTorr-1 Torr.

29. The system of claim 27, further comprising:
(a) a window mounted to the vacuum chamber;
(b) multiple sets of three-dimensionally looped inductive coils located adjacent the window and outside of the vacuum chamber; and
(c) a plane along which is located a central axis of a set of the coils, being substantially perpendicular to an exterior plane of the window.

30. The system of claim 27, wherein the specimen is biochar which is activated by the dense plasma.

31. The system of claim 27, wherein the specimen is a sol-gel film the optical and/or electrically conductive properties which are modified by the dense plasma.

32. The system of claim 27, further comprising:
(a) an oxygen gas tank operably supplying oxygen to the vacuum chamber for use in the plasma;
(b) a hydrogen gas tank operably supplying hydrogen for use in the plasma, after the oxygen; and
(c) a nitrogen gas tank operably supplying nitrogen for use in the plasma, after the hydrogen.

33. The system of claim 28, wherein the permanent magnets are longitudinally spaced apart ring magnets each surrounding the vacuum chamber, and further comprising a specimen longitudinally moving within the vacuum chamber inside a plasma and through openings of the ring magnets.
